(19) United States
(12) Patent Application Publication
(10) Pub. No.: US 2024/0431121 A1
(43) Pub. Date: Dec. 26, 2024

(54) MEMORY DEVICE AND MEMORY SYSTEM INCLUDING THE SAME

(71) Applicant: SAMSUNG ELECTRONICS CO., LTD., Suwon-si (KR)

(72) Inventors: Yunseok Yang, Suwon-si (KR); Jaewoo Shin, Suwon-si (KR); Minhwan An, Suwon-si (KR); Yunkyeong Jeong, Suwon-si (KR); Jin Suk Chung, Suwon-si (KR)

(21) Appl. No.: 18/434,014

(22) Filed: Feb. 6, 2024

(30) Foreign Application Priority Data
Jun. 22, 2023 (KR) 10-2023-0080426

(51) Int. Cl. H10B 80/00; H01L 25/065; H01L 25/18

(52) U.S. Cl. CPC H10B 80/00; H01L 25/0652; H01L 25/18; H01L 2225/06513; H01L 2225/06541

(57) ABSTRACT

The present disclosure relates to memory devices and memory systems. An example memory device includes a first core die, a second core die, and a base die stacked in a first direction. The base die is configured to output data of memory cells provided by the first and second core dies through a through-via. The through-via passes through the first and second core dies in the first direction with different burst lengths based on a mode signal.

### CROSS-REFERENCE TO RELATED APPLICATION

This application claims priority to and the benefit of Korean Patent Application No. 10-2023-0080426 filed in the Korean Intellectual Property Office on Jun. 22, 2023, the entire contents of which are incorporated herein by reference.

### BACKGROUND

As the amount of data to be processed by electronic devices increases, memory devices with high capacity and high bandwidth are required. To improve memory integration, three-dimensional (3D) disposing methods for stacking memory chips have been developed from the existing two-dimensional (2D) disposing method.

A high bandwidth memory (HBM) device may include vertically stacked semiconductor chips, and may electrically connect semiconductor chips through a through-via such as a through silicon via TSV.

However, as the number of data input/output pins and the number of data inputs/outputs of the high bandwidth memory device are fixed at relatively high values, there is a need to variously configure the number of data input/output pins and the rate of data transfer of the high bandwidth memory device to accommodate interconnectivity with external devices (e.g., a processor) that may have more or less number of data input/output pins and operate lower data transfer rate than that of the high bandwidth memory device.

### SUMMARY

The present disclosure relates to memory devices, including a memory device for exchanging data of the number of data input/output pins with external devices as well as a memory device for reducing a cost for a process relating to a size and a pitch of a configuration of an external device, and memory systems including the same.

In some implementations, a memory device includes: a first core die and a second core die stacked in a first direction, the first core die including first memory cells and the second core die including second memory cells and a base die stacked in the first direction with the first and second core dies, the base die configured to output data of the first memory cells and the second memory cells provided by the first core die and the second core die through a through-via, the through-via passing through the first core die and the second core die in the first direction with different burst lengths based on a mode signal.

In some implementations, a memory device includes: a first core die and a second core die stacked in a first direction, the first core die including first memory cells and the second core die including second memory cells and a base die stacked with the first and second core dies in the first direction, the base die configured to output data of the first memory cells and the second memory cells provided by the first core die and the second core die through a through-via, the through-via passing through the first core die and the second core die in the first direction, the base die including a first data bump and a second data bump connected to an external pad on one side and configured to output the data, a first data register connected to the first data bump, a second data register connected to the second data bump, and a multiplexer disposed between the first data register and the second data register.

In some implementations, a memory system includes a memory device including a first core die, a second core die, and a base die stacked in a first direction, the first core die including first memory cells, the second core die including second memory cells, the base die configured to output data of the first memory cells and the second memory cells provided by the first core die and the second core die through a through-via, and the through-via passing through the first core die and the second core die in the first direction to first data bumps and a memory controller configured to exchange the data with the memory device through second data bumps, wherein the number of the second data bumps is less than the number of the first data bumps.

### BRIEF DESCRIPTION OF THE DRAWINGS

FIG. 1 shows a configuration of an example of a memory system.

FIG. 2 shows an example of a memory system.

FIG. 3 shows a configuration of an example of a core die stacked body.

FIG. 4 shows an example enlarged view of a predetermined region of FIG. 2.

FIG. 5 and FIG. 6 show an example base die of a memory system and an example lower side of a memory controller.

FIG. 7 shows a configuration of another example of a memory device.

FIG. 8 shows an example of a memory device.

FIG. 9 and FIG. 10 show timing diagrams on an operation of an example of a memory device.

FIG. 11 shows a configuration of another example of a memory device.

FIG. 12 and FIG. 13 show timing diagrams on an operation of another example of a memory device.

FIG. 14 to FIG. 16 show another example of a memory system.

FIG. 17 and FIG. 18 show timing diagrams on an operation of another example of a memory device.

FIG. 19 shows another example of a memory system.

FIG. 20 shows another example of a memory system.

FIG. 21 shows a perspective view of a configuration of an example of a system device to which a memory system is applied.

FIG. 22 shows a perspective view of a configuration of another example of a system device to which a memory system is applied.

### DETAILED DESCRIPTION

In the following detailed description, only certain implementations of the present disclosure have been shown and described, simply by way of illustration. As those skilled in the art would realize, the described implementations may be modified in various different ways, all without departing from the spirit or scope of the present disclosure.

The drawings and description are to be regarded as illustrative in nature and not restrictive, and like reference numerals designate like elements throughout the specification.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations, such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

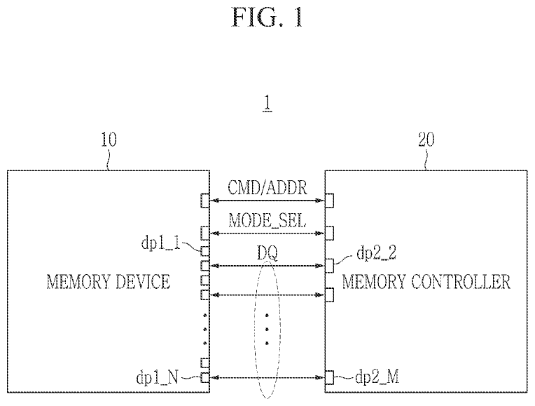

FIG. 1 shows a configuration of an example of a memory system.

Referring to FIG. 1, the memory system 1 includes a memory device 10 and a memory controller 20.

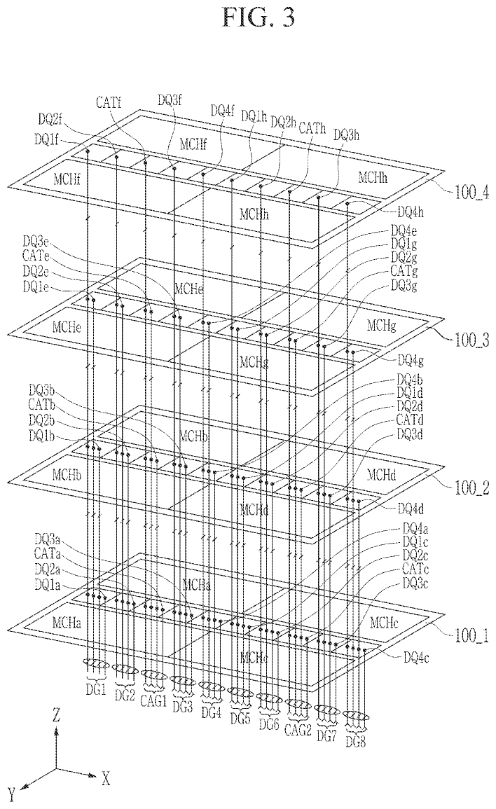

The memory device 10 may be a high bandwidth memory (HBM) device including memory channels MCHa to MCHh (refer to FIG. 3), and without being limited thereto, it may be a dynamic random access memory (DRAM) such as a double data rate synchronous dynamic random access memory (DDR SDRAM), a low power double data rate (LPDDR) SDRAM, a graphics double data rate (GDDR) SDRAM, or a rambus dynamic random access memory (RDRAM). The memory channels MCHa to MCHh may include a memory cell array including memory cells.

The memory controller 20 may provide various signals to the memory device 10 through a memory interface, a pin, or a bump to control memory operations such as write and read. The memory controller 20 may have an additional die shape, and depending on the implementation, it may be installed in a system on chip (SoC) die, a graphic processing unit (GPU) die, and a central processing unit (CPU) die.

For example, the memory controller 20 may provide a command CMD and an address ADDR to the memory device 10 to access data DQ on cells in the memory device 10. According to some implementations, the memory controller 20 may provide a mode signal MODE_SEL together with the command CMD and the address ADDR to the memory device 10 and may control an operation mode of the memory device 10 for a memory operation, and a technical scope of the present disclosure is not limited thereto.

Further, the memory device 10 may exchange the data DQ with the memory controller 20 through first data pads dp1_1 to dp1_N and second data pads dp2_1 to dp2_M between the memory controller 20 and the memory device 10. The M may be less than the N, which is not limited thereto. According to some implementations, the ratio of the number of the second data pads dp2_1 to dp2_M and the number of the first data pads dp1_1 to dp1_N may be 1:n, and the n may be an integer of equal to or greater than 2.

The memory controller 20 may access the memory device 10 according to a request from a host (HOST). The memory controller 20 may communicate with the host by use of various types of protocols, and for example, the memory controller 20 may communicate with the host by use of an interface protocol such as the PCI-E (Peripheral Component Interconnect-Express), the ATA (Advanced Technology Attachment), the SATA (Serial ATA), the PATA (Parallel ATA) or the SAS (serial attached SCSI). In addition, other various types of the interface protocols such as the USB (Universal Serial Bus), the MMC (Multi-Media Card), the ESDI (Enhanced Small Disk Interface), or the IDE (Integrated Drive Electronics) may be applied to the protocol between the host and the memory controller 20.

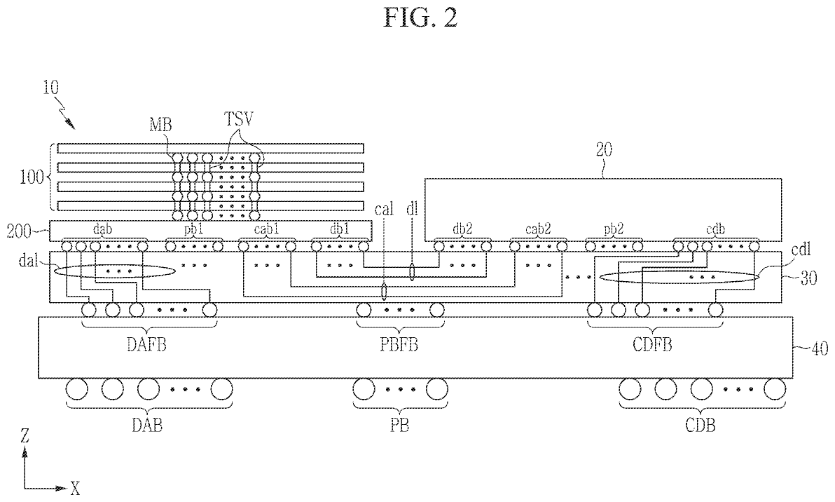

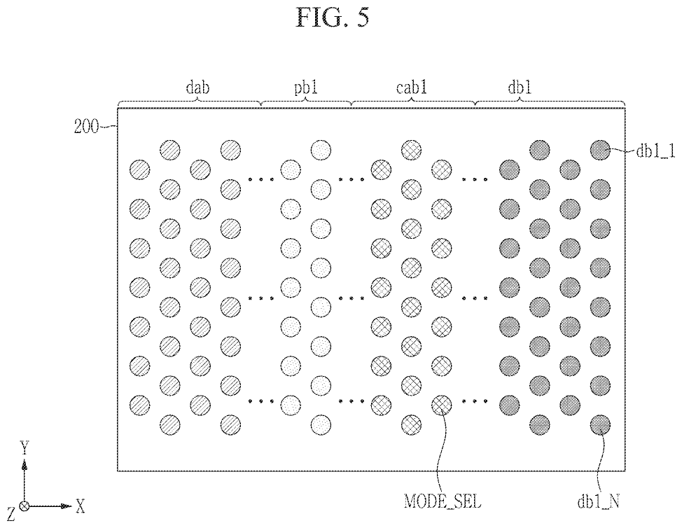

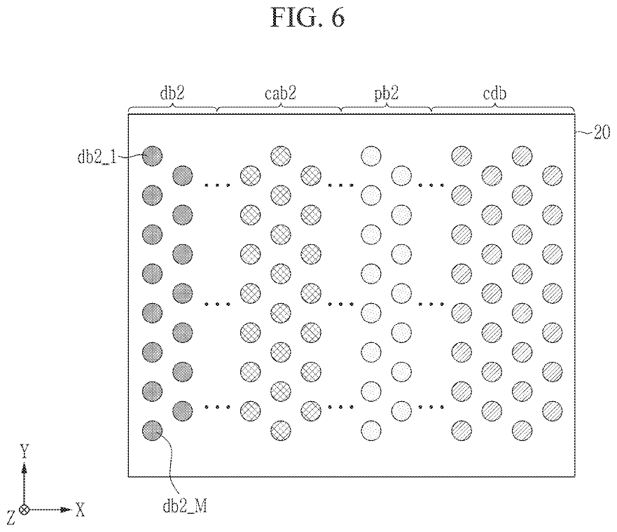

FIG. 2 to FIG. 4 shows an example of a memory system. FIG. 5 and FIG. 6 show an example base die of a memory device and an example lower side of a memory controller.

Referring to FIG. 1 to FIG. 6, the memory system 1 includes a memory device 10, a memory controller 20, an interposer 30, and a printed circuit board (PCB) 40.

The memory device 10 may include a memory die 100 including four core dies 100_1 to 100_4 stacked in a third direction Z and a base die 200. First bumps MB may be formed between the stacked core dies 100_1 to 100_4 and the base die 200, and a through silicon via TSV, a kind of through-via, passing through the core dies 100_1 to 100_4 may be formed among the stacked first bumps MB.

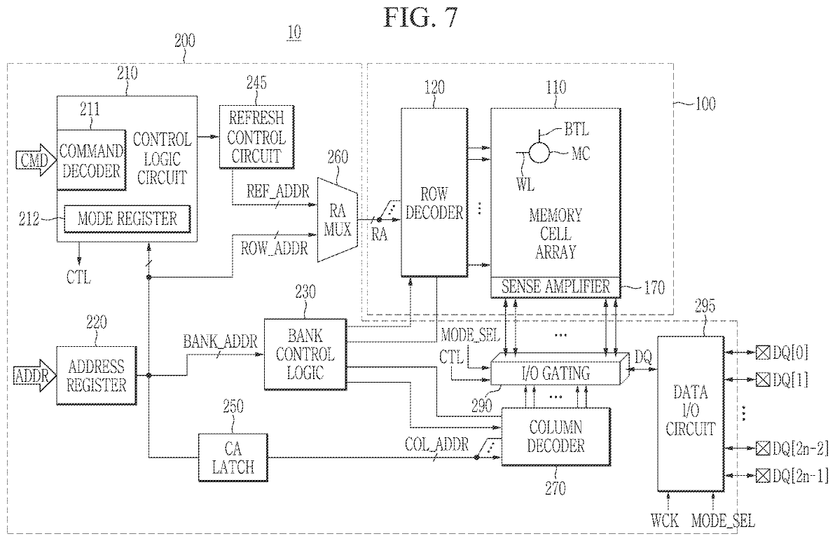

First direct access bumps dab, first power bumps pb1, first command and address bumps cab1, and first data bumps db1 may be disposed on a lower side of the base die 200 with respect to the third direction Z. Although not shown, the base die 200 may include a data input/output buffer 295 (refer to FIG. 7) connected to the first data bumps db1 and transmitting/receiving data.

Referring to FIGS. 2 and 3, although only four core dies are shown, one or more embodiments are not limited thereto, and the core dies may be variously configured to have more than or less than four. In addition, the base die 200 may be stacked not on a lower portion of the stacked core dies but on an upper portion thereof.

FIG. 3 shows a configuration of four stacked core dies 100_1 to 100_4, and the respective stacked core dies 100_1 to 100_4 may include two memory channels MCHa and MCHc, MCHb and MCHd, MCHe and MCHg, and MCHf and MCHh, and the respective memory channels MCHa to MCHh may include a predetermined number of memory banks.

The memory channels MCHa, MCHb, MCHe, and MCHf may be disposed on the left side of the core dies 100_1 to 100_4 with respect to an XY-plane, and the memory channels MCHc, MCHd, MCHg, and MCHh may be disposed on the right side of the core dies 100_1 to 100_4 with respect to the XY-plane. The memory channels MCHa to MCHh may respectively divided into top and bottom in the corresponding core dies 100_1 to 100_4 and may then be disposed. Corresponding data terminals DQ1a to DQ4a, DQ1b to DQ4b, DQ1e to DQ4e, and DQ1f to DQ4f and corresponding command and address terminals CATa, CATb, CATe, and CATf may be included among the divided and disposed memory channels MCHa, MCHb, MCHe, and MCHf, and corresponding data terminals DQ1c to DQ4c, DQ1d to DQ4d, DQ1g to DQ4g, and DQ1h to DQ4h and corresponding command and address terminals CATc, CATd, CATg, and CATh may be included among the divided and disposed memory channels MCHc, MCHd, MCHg, and MCHh. A first data group DG1 may be transmitted through data terminals DQ1a, DQ1b, DQ1e, and DQ1f, and a second data group DG2 may be transmitted through data terminals DQ2a, DQ2b, DQ2e, and DQ2f. In this way, third to eighth data groups DG3 to DG8 may be transmitted through other data terminals DQ3a to DQ4h. A first command and address group CAG1 may be transmitted through command and address terminals CATa, CATb, CATe, and CATf, and a second command and address group CAG2 may be transmitted through command and address terminals CATc, CATd, CATg, and CATh.

Although not shown, the data input/output buffer 295 shown in FIG. 7 may be connected to corresponding data terminals DQ1a to DQ4a, DQ1b to DQ4b, DQ1c to DQ4c, DQ1d to DQ4d, DQ1e to DQ4e, DQ1f to DQ4f, DQ1g to DQ4g, and DQ1h to DQ4h.

Referring to FIG. 3, the data terminals and the command and address terminals may be the first bumps MB shown in FIG. 2, respectively. Further, lines vertically passing through the data terminals and the command and address terminals may be the TSV.

Assuming that n-bit data are input/output through the respective data terminals DQ1a-DQ4a, . . . , DQ1h-Q4h, the total of 32n-bit data may be input/output through the entire data terminals. Assuming that k-bit command and address are input/output through the respective command and address terminals CATa to ATh, the total of 8k-bit command and address may be input/output through the entire command and address terminals.

As shown in FIG. 3, the second to eighth data groups DG2 to DG8 are configured to be identical with lines that correspond to the first data group DG1, and the second command and address group CAG2 are configured to be identical with lines that correspond to the first command and address group CAG1.

The core dies 100_1 to 100_4 shown in FIG. 2 and FIG. 3 may be manufactured to be a memory device for respectively storing data that are input through data terminals to selected memory cells from among memory cells of a memory cell array in response to the command and address received through the command and address terminals or outputting the data stored in the selected memory cells through data terminals.

Second command and address bumps cab1, second data bumps db2, second power bumps pb2, and first control signal bumps cdb may be disposed on a lower side of the memory controller 20. Although not shown, the memory controller 20 may include a buffer connected to the second data bumps db2.

The first bumps MB, the first direct access bumps dab, the first and second power bumps pb1 and pb2, the first and second command and address bumps cab1 and cab2, the first and second data bumps db1 and db2, and the first control signal bumps cdb may be micro bumps.

Second direct access bumps DAFB, third power bumps PBFB, and second control signal bumps CDFB may be disposed on a lower side of the interposer 30. The interposer 30 may include a direct line dal for connecting the first direct access bumps dab and the second direct access bumps DAFB; a command and address line cal for connecting the first command and address bumps cab1 and the second command and address bumps cab2; and control signal lines cdl for connecting the first data bumps db1, the second data bumps db2, the data lines dl, the first control signal bumps cdb, and the second control signal bumps CDFB.

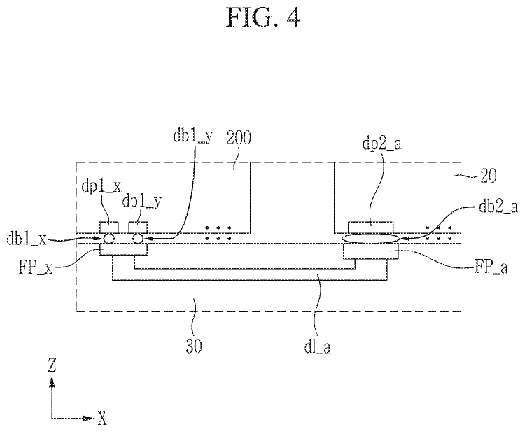

As shown in FIG. 4 to FIG. 6, the first data bumps db1 include 1 to N first data bumps db1_1 to db1_N, and the second data bumps db2 include 1 to M data second bumps db2_1 to db2_M. According to some implementations, the number of the second data bumps db2 may be less than the number of the first data bumps db1, and a ratio of the M and the N may be 1 to n, and the n is an integer of equal to or greater than 2. Depending on some implementations, the n may be 2 or 4. As shown in FIG. 4, FIG. 5, and FIG. 6, the ratio of the number of the second data pads dp2_1 to dp2_M and the number of the first data pads dp1_1 to dp1_N is 1 to 2, although other ratios may be used.

The first data bumps db1 may include a data pad. For example, first_x and first_y data bumps db1_x and db1_y included in the first data bumps db1 may include first_x and first_y data pads dp1_x and dp1_y. Further, the second data bumps db2 may respectively include a data pad. For example, a second_a data bump db2_a included in the second data bumps db2 may include a second_a data pad dp2_a.

The first data bumps db1 and the second data bumps db2 may be electrically connected through interposer pads FP_x and FP_a and a data line dl_a disposed on an upper side of the interposer 30. According to some implementations, the first_x and first_y data bumps db1_x and db1_y may be connected to an x-th interposer pad FP_x, and the x-th interposer pad FP_x may be connected to an a-th data line dl_a and the a-th interposer pad FP_a and may transmit/receive data to/from the second_a data pad dp2_a. According to some implementations, the ratio between the number of the interposer pads connected to the data bumps db1 and the number of data bumps db1 may be 1 to n, and n may be an integer of equal to or greater than 2.

According to some implementations, the second data bumps db2 and the data lines dl may correspond one-to-one, and the second_a data bump db2_a and the first data line dl_a may correspond to each other. According to some implementations, the number of the data lines dl may be less than the number of the first data bumps db1 and the number ratio of the first data bumps db1 and the data lines dl may be equal to the number ratio of the first data bumps db1 and the second data bumps db2. According to some implementations, the ratio between the number of the data lines dl and the number of the first data bumps db1 may be 1 to n, and n may be an integer of equal to or greater than 2, like 2 or 4. As shown in FIG. 4, FIG. 5 and FIG. FIG. 6, the ratio between the number of the data lines dl and the number of the first data bumps db1 may be 1 to 2.

Through the ratio of the number of the second data pads dp2_1 to dp2_M and the number of the first data pads dp1_1 to dp1_N, and the ratio of the number of the data lines dl and the first data bumps db1, the memory system 1 may provide a memory controller and an interposer for reducing the cost of processes relating to the size and the pitch of the configuration.

Although not shown, the interposer 30 may additionally include power lines for connecting the first power bumps pb1 and the third power bumps PBFB and connecting the second power bumps pb2 and the third power bumps PBFB. The second direct access bumps DAFB, the third power bumps PBFB, and the second control signal bumps CDFB may be flip die bumps.

Direct access balls DAB, power balls PB, and control signal balls CDB may be disposed on a lower side of the PCB 40.

The second direct access bumps DAFB may be connected to the direct access balls DAB, the third power bumps PBFB may be connected to the power balls PB, and the second control signal bumps CDFB may be connected to the control signal balls CDB on the PCB 40.

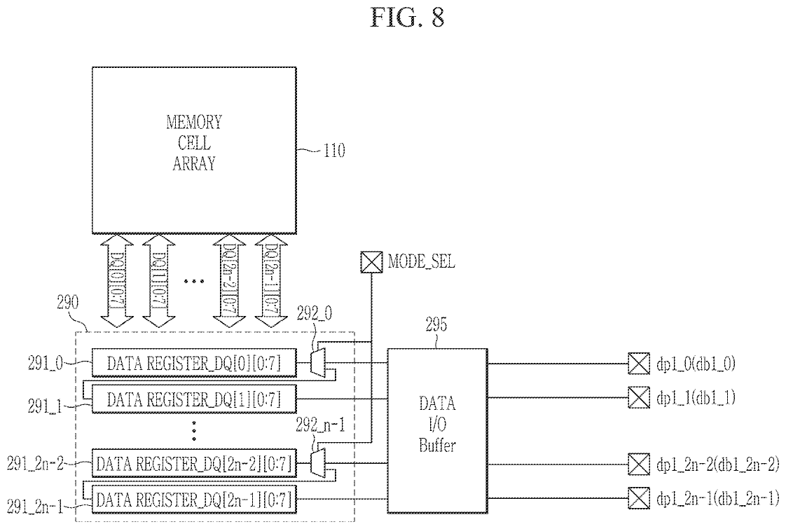

FIG. 7 shows a configuration of another example of a memory device. FIG. 8 shows an example of a memory device.

Referring to FIG. 7 and FIG. 8, the memory device 10 includes a memory cell array 110, a row decoder 120, a sense amplifier 170, a control logic circuit 210, an address register 220, a bank control logic 230, a refresh control circuit 245, a column address latch 250, a row address multiplexer 260, a column address latch 250, a column decoder 270, an input/output gating circuit 290 and a data input/output buffer 295.

The memory cell array 110 may include a predetermined number of memory banks (not shown) included in the memory channels MCHa to MCHh. Depending on some implementations, the sense amplifier 170, the row decoder 120, and the column decoder 270 may include bank sense amplifiers, bank row decoders, and bank row decoders connected to respective memory banks, which is not limited thereto.

The memory cell array 110 may include word lines WL, bit lines BL, and memory cells MC disposed at points on which the word lines WL cross the bit lines BL.

The control logic circuit 210 may control an operation of the memory device 10. For example, the control logic circuit 210 may generate control signals so that the memory device 10 may perform a write operation or a read operation. The control logic circuit 210 may include a command decoder 211 for decoding a command CMD provided by the memory controller 20 and a mode register 212 for setting an operation mode of the memory device 10.

For example, the command decoder 211 may decode a write enable signal, a row address strobe signal, a column address strobe signal, and a channel selection signal to generate a control signal CTL that corresponds to the command CMD.

The mode register 212 may store setting information for setting the operation mode of the memory device 10. The memory controller 20 may perform a mode register write operation MRW to store the setting information in the mode register 212. The memory controller 20 may perform a mode register read operation MRR to receive the setting information stored in the mode register 212 from the memory device 10.

The address register 220 may receive an address ADDR including a bank address BANK_ADDR, a row address ROW_ADDR, and a column address COL_ADDR from the memory controller 20. The address register 220 may provide the received bank address BANK_ADDR to the bank control logic 230, and may provide the received row address ROW_ADDR to the row address multiplexer 260.

The bank control logic 230 may generate bank control signals in response to the bank address BANK_ADDR. The row decoder 120 and the column decoder 270 may activate the corresponding bank in response to the bank control signals.

The row address multiplexer 240 may receive the row address ROW_ADDR from the address register 220, and may receive a refresh row address REF_ADDR from the control logic circuit 210. The row address multiplexer 240 may selectively output the row address ROW_ADDR or the refresh row address REF_ADDR as a row address RA. The row address RA output by the row address multiplexer 240 may be applied to the row decoder 120.

The column address latch 250 may receive the column address COL_ADDR from the address register 220, and may temporarily store the column address COL_ADDR. The column address latch 250 may gradually increase the column address COL_ADDR in a burst mode. The column address latch 250 may apply the temporarily stored or gradually increased column address to the column decoder 270.

The column decoder 270 may, relating to the bank activated by the bank control logic 230, activate the sense amplifier corresponding to the bank address BANK_ADDR and the column address COL_ADDR through the input/output gating circuit 290.

The input/output gating circuit 290 may include input/output data gating circuits, input data mask logics, data registers 291_0 to 291_2n−1, and multiplexers 292_0 to 292_n−1. The input/output gating circuit 290 may receive a control signal CTL from the control logic circuit 210, and may receive a mode signal MODE_SEL from the memory controller 20. According to some implementations, as shown in FIG. 5, the mode signal MODE_SEL may be input to the input/output gating circuit 290 through the first command and address bump cab1.

The respective data registers 291_0 to 291_2n−1 may input/output data DQ[0] to DQ[2n−1] to/from the first data pads dp1_0 to dp1_2n−1 through the data input/output buffer 295. For ease of description, reference numerals of the first data pads dp1_1 to dp1_N shown in FIG. 5 are different from the reference numerals of the first data pads dp1_0 to dp1_2n−1 shown in FIG. 8, but the respective configurations shown in FIG. 5 and FIG. 8 are the same according to the technical scope of the present disclosure. Depending on some implementations, N of FIG. 5 may be equal to 2n of FIG. 8. The bit lines corresponding to burst length BL may be simultaneously accessed so as to support the burst mode on the burst length for indicating a maximum number of column locations for accessing the bit lines by the memory device 10. The data registers 291_0 to 290_2n−1 may temporarily store the simultaneously accessed bits in order in the burst mode, and the burst length may be set to be 8 as shown in the drawing, which is not limited thereto.

The multiplexers 292_0 to 292_n−1 may be disposed between the even numbered data registers 291_0, . . . , 291_2n−2 and the odd numbered data registers 291_1, . . . , 291_2n−1. In the present disclosure, the multiplexers 292_0 to 292_n−1 may determine a data path input/output according to the input mode signal MODE_SEL. Further, the multiplexers 292_0 to 292_n−1 may be operable as multiplexers or demultiplexers according to the operation of the memory device 10.

At the read operation of the memory device 10, the multiplexers 292_0 to 292_n−1 may output the data DQ[0], . . . , DQ[2n−2] output by the even numbered data registers 291_0, . . . , 291_2n−2 to the even numbered first data pads dp1_0, . . . , dp1_2n−2 through the data input/output buffer 295 according to the mode signal MODE_SEL. The multiplexers 292_0 to 292_n−1 may output the data DQ[0], . . . , DQ[2n−2] output by the even numbered data registers 291_0, . . . , 291_2n−2 to the odd numbered data registers 291_1, . . . , 291_2n−1 according to the mode signal MODE_SEL.

According to some implementations, the data pad connected to the data registers disposed on respective sides of one multiplexer therebetween may be connected to one interposer pad.

For example, the first_0 data pad dp1_0 connected to the 0-th data register 291_0 and the first_1 data pad dp1_1 connected to the first data register 291_1 may correspond to the first_x data pad dp1_x and the first_y data pad dp1_y of FIG. 4, and the first_0 data pad dp1_0 and the first_1 data pad dp1_1 may be connected to one interposer pad disposed on the interposer 30. Descriptions on the first_0 data pad dp1_0 and the first_1 data pad dp1_1 may be respectively applied to the even numbered first data pads dp1_0, . . . , dp1_2n−2 and the odd numbered first data pads dp1_1, . . . , dp1_2n−1.

The data input/output buffer 295 may synchronize the data DQ input/output by the memory controller 20 with data clocks WCK, and may distinguish the input data and the output data. According to some implementations, the data input/output buffer 295 may receive the mode signal MODE_SEL and may control an operation of an input or output interface.

According to some implementations, the memory cell array 110, the row decoder 120, and the sense amplifier 170 may be included in the memory die 100, and the control logic circuit 210, the address register 220, the bank control logic 230, the refresh control circuit 245, the column address latch 250, the row address multiplexer 260, the column address latch 250, the column decoder 270, the input/output gating circuit 290, and the data input/output buffer 295 may be included in the base die 200.

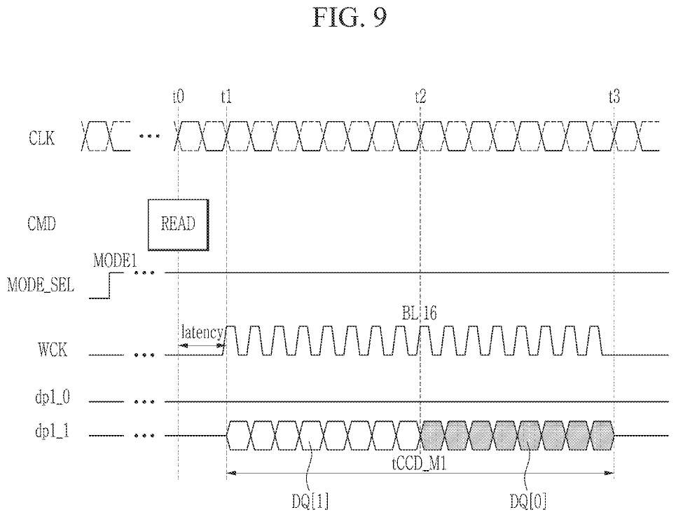

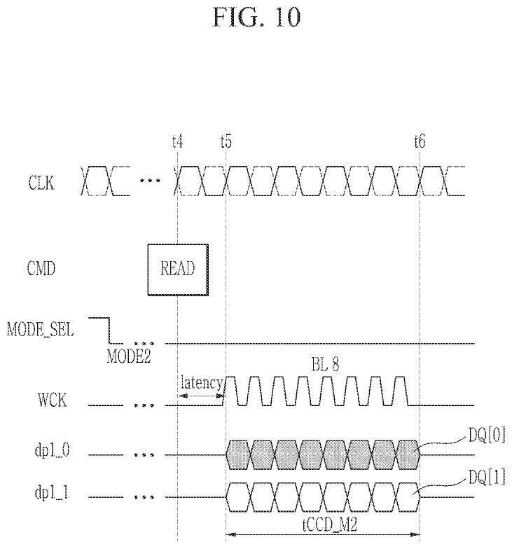

FIG. 9 and FIG. 10 show timing diagrams on an operation of an example of a memory device.

A first operation mode of the memory device 10 of FIG. 1 to FIG. 8 may be described with reference to FIG. 9, and a second operation mode of the memory device 10 of FIG. 1 to FIG. 8 may be described with reference to FIG. 10.

Referring to FIG. 7 to FIG. 9, before the 0-th time to, the mode signal MODE_SEL on a first level MODE1 is input to the multiplexers 292_0 to 292_n−1. The multiplexers 292_0 to 292_n−1 of the memory device 10 may operate in a first operation mode based on the mode signal MODE_SEL at the first level MODE1. In the first operation mode, the multiplexers 292_0 to 292_n−1 of the memory device 10 may output the data to the first burst length through the odd numbered first data pads dp1_1, . . . , dp1_2n−1 from among the first data pads.

For example, at the 0-th time to, a read command is input, and the first data DQ[1] and the 0-th data DQ[0] may be output with the burst length of 16 to the first_1 data pad dp1_1 from the first time t1 to the third time t3.

From the first time t1 to the second time t2, the first_1 data register 291_1 may output the first data DQ[1] to the first_1 data pad dp1_1 through the data input/output buffer 295, and the 0-th multiplexer 292_0 may provide the 0-th data DQ[0] provided to the first_0 data register 291_0 to the first_1 data register 291_1.

From the second time t2 to the third time t3, the 0-th data register 291_0 may not perform an output operation to the first_0 data pad dp1_0. The first data register 291_1 may output the 0-th data DQ[0] provided by the 0-th multiplexer 292_0 to the first_1 data pad dp1_1 through the data input/output buffer 295.

From the first time t1 to the third time t3, descriptions on the operations of the 0-th data register 291_0, the first data register 291_1, and the 0-th multiplexer 292_0 may be applied to the even numbered first data registers 291_0, . . . , 291_2n−2, the odd numbered first data registers 291_1, . . . , 291_2n−1, and the multiplexers 292_0 to 292_n−1. As described above, in the first operation mode, DQ[1] and DQ[0] may be output only through the first_1 data pad dp1_1 at, for example, the burst length of 16. The first operation mode may also be referred to as half-mode.

Referring to FIG. 10, before the fourth time t4, the mode signal MODE_SEL on a second level MODE2 may be input to the multiplexers 292_0 to 292_n−1. The multiplexers 292_0 to 292_n−1 of the memory device 10 may operate in a second operation mode based on the mode signal MODE_SEL at the second level MODE2. In the second operation mode, the multiplexers 292_0 to 292_n−1 of the memory device 10 may output the data with a second burst length that is less than the first burst length through the first data pads dp1_0 to dp1_2n−1. According to some implementations, ratio of the second burst length and first burst length is 1 to n, and the n is an integer of equal to or greater than 2.

For example, at the fourth time t4, a read command is input, and after latency, the 0-th data DQ[0] and the first data DQ[1] may be output at the burst length of 8 on the first_0 data pad dp1_0 and the first_1 data pad dp1_1, respectively, for the fifth time t5 to the sixth time t6.

From the fifth time t5 to the sixth time t6, the 0-th data register 291_0 may output the 0-th data DQ[0] to the first_0 data pad dp1_0 through the 0-th multiplexer 292_0 and the data input/output buffer 295, and the first data register 291_1 may output the first data DQ[1] to the first_1 data pad dp1_1 through the data input/output buffer 295.

From the fifth time t5 to the sixth time t6, descriptions on the operations of the 0-th data register 291_0, the first data register 291_1, and the 0-th multiplexer 292_0 may be applied to the even numbered first data registers 291_0, . . . , 291_2n−2, the odd numbered first data registers 291_1, . . . , 291_2n−1, and the multiplexers 292_0 to 292_n−1. As described above, in the second operation mode, DQ[1] and DQ[0] may be output at the burst length of 8 through the first_1 data pad dp1_1 and the first_0 data pad dp1_0, respectively. The second operation mode may also be referred to as full-mode.

Referring to FIG. 9 and FIG. 10, a first minimum burst section tCCD_M1 in the first operation mode MODE1 for the burst mode is twice a second minimum burst section tCCD_M2 in the second operation mode MODE2 for the burst mode. That is, the first burst mode (e.g., half-mode) of the first operation mode is twice as large as the second burst mode of the second operation mode (e.g., full-mode).

The device has been described to be operated in different operation mode depending on the level of the mode signal MODE_SEL, and the mode signal MODE_SEL for changing the operation mode of the multiplexers 292_0 to 292_n−1 is not limited thereto.

The memory device 10 may adjust the bump for inputting/outputting data through the mode signal MODE_SEL without any change of the configuration, thereby universally exchanging data with external devices in the viewpoint of the number of the data bumps.

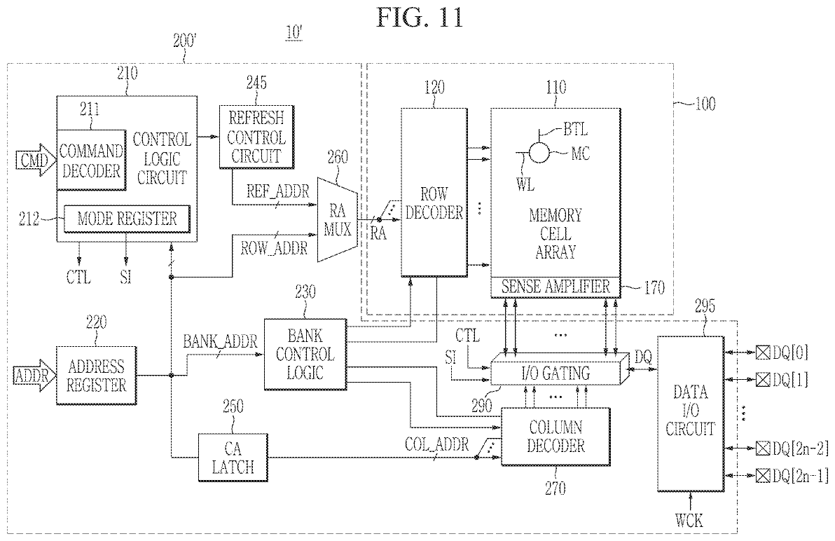

FIG. 11 shows a configuration of another example of a memory device.

The memory device 10′ of FIG. 11 may be described in comparison to the memory device 10 of FIG. 7, and their differences will be focused for ease of description. The configuration of the memory device 10′ that is not described will be replaced with the description on the corresponding configuration of the memory device 10 of FIG. 7.

Referring to FIG. 8 and FIG. 11, the input/output gating circuit 290 receives setting information SI on the burst mode MODE from the mode register 212 of the control logic circuit 210, and the setting information SI is latched and is input to the multiplexers 292_0 to 292_n−1, and the operations of the multiplexers 292_0 to 292_n−1 may be controlled.

The multiplexers 292_0 to 292_n−1 may determine the input/output data path according to the latched setting information SI.

The multiplexers 292_0 to 292_n−1 may output the data DQ[0], . . . , DQ[2n−2] output by the even numbered data registers 291_0, . . . , 291_2n−2 to the even numbered first data pads dp1_0, . . . , dp1_2n−2 through the data input/output buffer 295 according to the setting information SI. Further, the multiplexers 292_0 to 292_n−1 may output the data DQ[0], . . . , DQ[2n−2] output by the even numbered data registers 291_0, . . . , 291_2n-2 to the odd numbered data registers 291_1, . . . , 291_2n−1 according to the setting information SI.

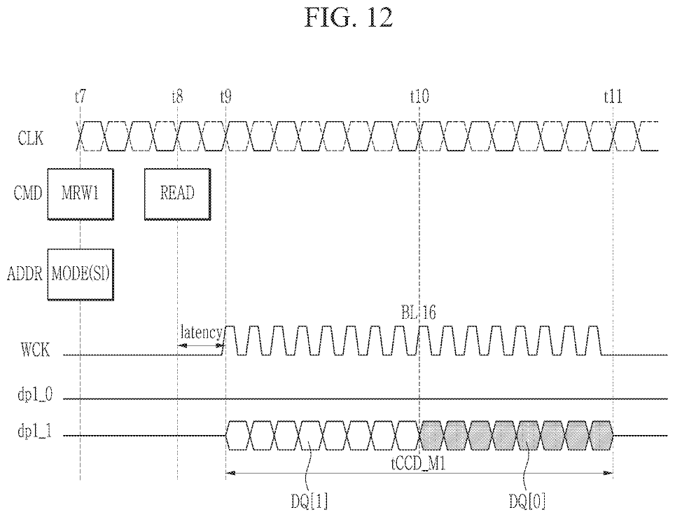

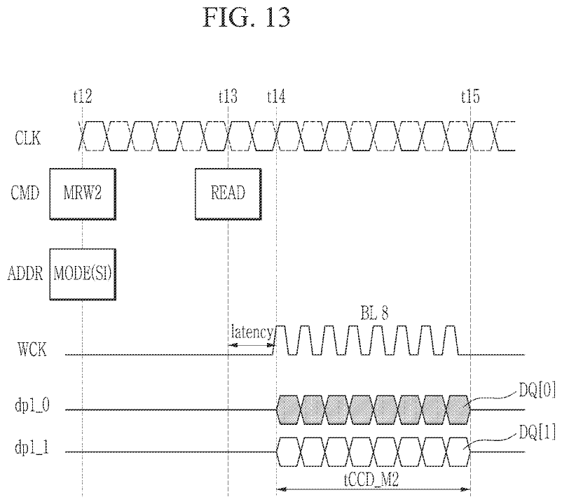

FIG. 12 and FIG. 13 show timing diagrams on an operation of another example of a memory device.

The first operation mode MODE1 of the memory device 10′ of FIG. 11 may be described with reference to FIG. 12, and the second operation mode MODE2 of the memory device 10′ of FIG. 11 may be described with reference to FIG. 13.

Referring to FIG. 11 and FIG. 13, for the seventh time t7 that is before the eighth time t8, the memory controller 20 may perform a first mode register write MRW1 operation for the burst mode MODE from among the setting of the mode register 212. The first mode register write MRW1 may correspond to the first operation mode MODE1 of FIG. 9. The setting information SI to which the first mode register write MRW1 operation is performed may be input to the multiplexers 292_0 to 292_n−1 in substitute for the mode signal MODE_SEL of FIG. 8. The multiplexers 292_0 to 292_n−1 to which the setting information SI is input may be operable in a similar way to the multiplexers 292_0 to 292_n−1 to which the mode signal MODE_SEL on the first level MODE1 shown in FIG. 8 and FIG. 9 is input.

Descriptions on the operations of the first data registers 291_0 to 291_2n−1 and the multiplexers 292_0 to 292_n−1 for the eighth time t8 to the eleventh time t11 may be replaced with the descriptions of the operations of the first data registers 291_0 to 291_2n−1 and the multiplexers 292_0 to 292_n−1 for the 0-th time to to the third time t3 of FIG. 9.

For the twelfth time t12 that is before the thirteenth time t13, the memory controller 20 may perform a second mode register write MRW2 operation on the burst mode MODE from among the setting of the mode register 212. The second mode register write MRW2 may correspond to the second operation mode MODE2 of FIG. 10. The setting information SI to which the second mode register write MRW2 operation is performed may be substituted with the mode signal MODE_SEL of FIG. 8 and may be input to the multiplexers 292_0 to 292_n−1. The multiplexers 292_0 to 292_n−1 to which the setting information SI is input may be operable in a similar way to the multiplexers 292_0 to 292_n−1 to which the mode signal MODE_SEL on the second level MODE2 of FIG. 8 and FIG. 10 is input.

Descriptions on the operations of the first data registers 291_0 to 291_2n−1 and the multiplexers 292_0 to 292_n−1 for the thirteenth time t13 to the fifteenth time t15 may be replaced with the descriptions of the operations of the first data registers 291_0 to 291_2n−1 and the multiplexers 292_0 to 292_n−1 for the 0-th time to to the third time t3 of FIG. 10.

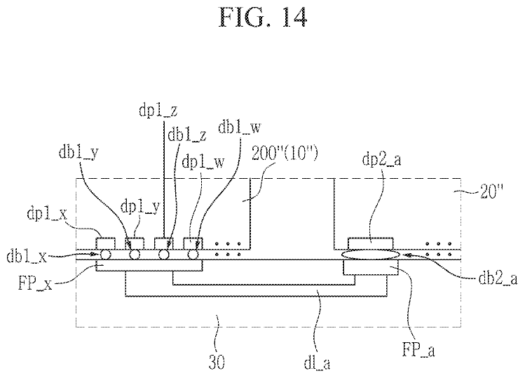

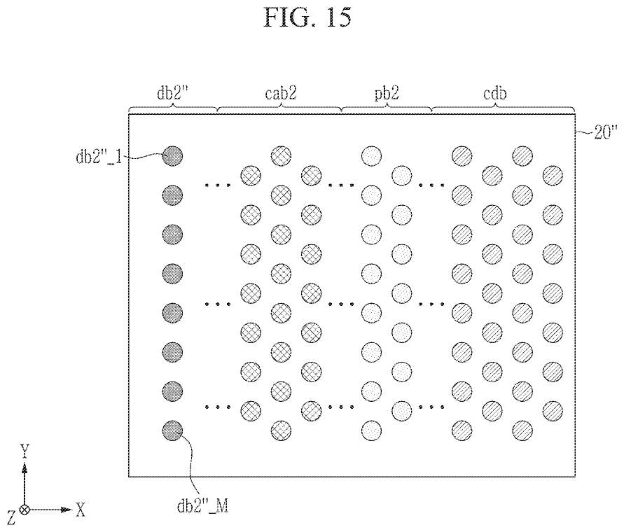

FIG. 14 to FIG. 16 show another example of a memory system.

The memory device 10″ and the memory controller 20″ of FIG. 14 to FIG. 16 may be described in comparison to the memory device 10 and the memory controller 20 of FIG. 4, FIG. 6, and FIG. 8, and their differences will be focused for ease of description. The configurations of the memory device 10″ and the memory controller 20″ that are not described will be replaced with the description on the corresponding configurations of the memory device 10 and the memory controller 20 of FIG. 4, FIG. 6, and FIG. 8.

The first data bumps db1 may respectively include a data pad. For example, the first_x, first_y, first_z, and first_w data bumps db1_x, db1_y, db1_z, and db1_w included in the first data bumps db1 may include the first_x, first_y, 1 first_z, first_w data pads db1_x, db1_y, db1_z, and db1_w. Further, the second data bumps db2″ may respectively include a data pad. For example, the second_a data bump db2_a included in the second data bump db2″ may include a second_a data pad dp2_a.

The first data bumps db1 and the second data bumps db2″ may be electrically connected through the interposer pads FP_x and FP_a and the data line dl_a dispose on an upper side of the interposer 30. According to some implementations, the included first_x, first_y, first_z, and first_w data bumps db1_x, db1_y, db1_z, and db1_w may be connected to an x-th interposer pad FP_x, and the x-th interposer pad FP_x may be connected to the a-th data line dl_a and the a-th interposer pad FP_a to transmit/receive data to/from the second_a data pad dp2_a.

As shown in FIG. 14, the ratio of the number of the data lines dl and the number of the first data bumps db1 may be 1 to 4, and the ratio of the number of the second data bumps db2″ and the number of the first data bumps db1 may be 1 to 4.

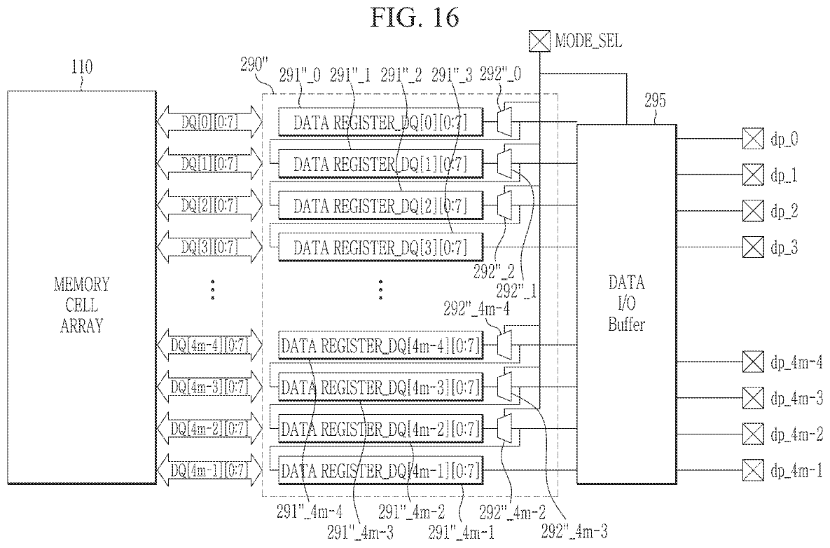

The input/output gating circuit 290″ may include data registers 291″_0 to 291″_4m-1. The respective data registers 291″_0 to 290″_4m-1 may input/output the data DQ[0] to DQ[4m-1] to/from the first data pads dp1_0 to dp1_4m-1 through the data input/output buffer 295. According to some implementations, 2n of FIG. 8 may be equal to 4m of FIG. 16.

4X-th multiplexers 292″_0, . . . , 292″_4m-4 may be disposed between 4X-th data registers 291″_0, . . . , 291″_4m-4 and (4X+1)-th data registers 291″_1, . . . , 291″_4m-3, (4X+1)-th multiplexers 292″_1, . . . , 292″_4m-3 may be disposed between the (4X+1)-th data registers 291″_1, . . . , 291″_4m-3 and (4X+2)-th data registers 291″_2, . . . , 291″_4m-2, and (4X+2)-th multiplexers 292″_2, . . . , 292″_4m-2 may be disposed between the (4X+2)-th data registers 291″_2, . . . , 291″_4m-2 and (4X+3)-th data registers 291″_3, . . . , 291″_4m-1. The X may be an integer of equal to or greater than 0, and may be less than m.

In the present disclosure, the multiplexers 292″_0, . . . , 292″_4m-2 may determine the data path input/output according to the input mode signal MODE_SEL. Further, the multiplexers 292″_0, . . . , 292″_4m-2 may be operable as multiplexers or demultiplexers according to the operation of the memory device 10.

According to some implementations, the data pads connected to the four data registers disposed with the multiplexer therebetween may be connected to the interposer pad.

For example, the first_0 data pad dp1_0 connected to the 0-th data register 291″_0, the first_1 data pad dp1_1 connected to the first data register 291″_1, the first_2 data pad dp1_2 connected to the second data register 291″_2, and the first_3 data pad dp1_3 connected to the third data register 291″_3 may correspond to the first_x data pad dp1_x, the first_y data pad dp1_y, the first_z data pad dp1_z, and the first_w data pad dp1_w of FIG. 14, and the first_0 data pad dp1_0, the first_1 data pad dp1_1, the first_2 data pad dp1_2, and the first_3 data pad dp1_3 may be connected to one interposer pad disposed on the interposer 30. Descriptions on the first_0 data pad dp1_0, the first_1 data pad dp1_1, the first_2 data pad dp1_2, and the first_3 data pad dp1_3 may be applied to the 4X-th first data pads dp1_0, . . . , dp1_4m-4, the (4X+1)-th first data pads dp1_1, . . . , dp1_4m-3, the (4X+2)-th first data pads dp1_2, . . . , dp1_4m-2, and the (4X+3)-th first data pads dp1_3, . . . , dp1_4m-1. The X may be an integer of equal to or greater than 0, and may be less than m.

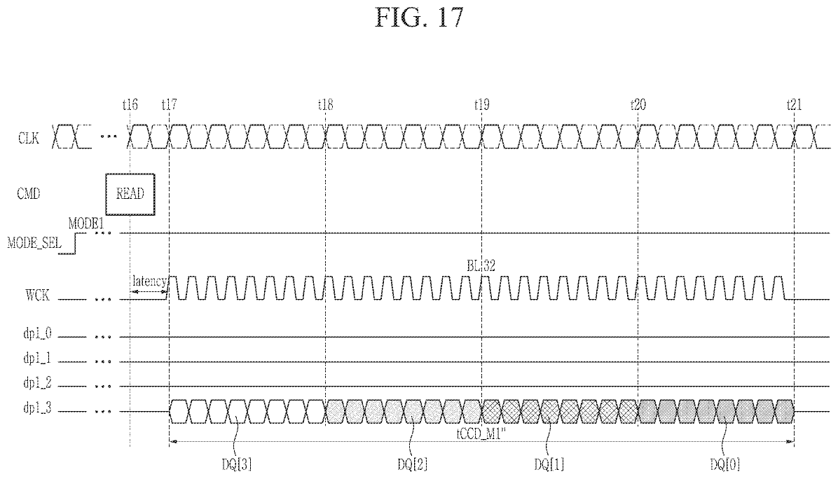

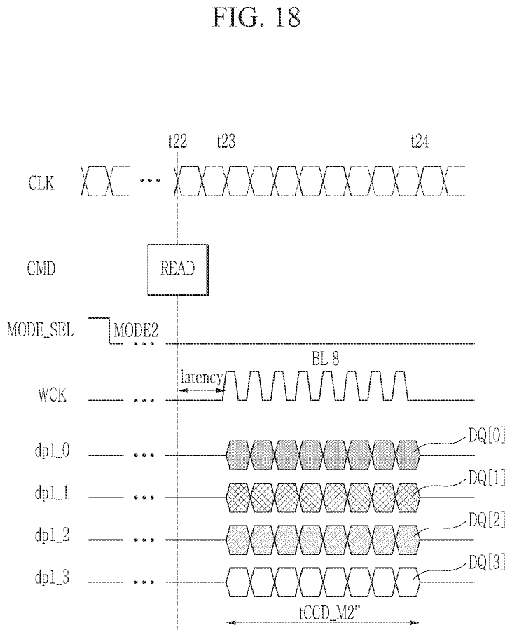

FIG. 17 and FIG. 18 show timing diagrams on an operation of another example of a memory device.

The first operation mode of the memory device 10″ of FIG. 14 to FIG. 16 may be described with reference to FIG. 17, and the second operation mode of the memory device 10″ of FIG. 14 to FIG. 16 may be described with reference to FIG. 18.

Referring to FIG. 14 to FIG. 18, before the sixteenth time t16, the mode signal MODE_SEL on the first level MODE1 may be input to the multiplexers 292″_0, . . . , 292″_4m-2. The multiplexers 292″_0, . . . , 292″_4m-2 of the memory device 10″ may be operable in the first operation mode based on the mode signal MODE_SEL on the first level MODE1. In the first operation mode, the multiplexers 292″_0, . . . , 292″_4m-2 of the memory device 10 may output the data with the first burst length through the (4X+3)-th first data pads dp1_3, . . . , dp1_4m-1 from among the first data pads.

For the seventeenth time t17, a read command is input, and after latency, the third data DQ[3], the second data DQ[2], the first data DQ[1], and the 0-th data DQ[0] may be output with the burst length of 32 on the first_3 data pad dp1_3 for the seventeenth time t17 to the twenty-first time t21.

For the seventeenth time t17 to the eighteenth time t18, the third data register 291″_3 may output the third data DQ[3] to the first_3 data pad dp1_3 through the data input/output buffer 295, the second multiplexer 292″_2 may output the second data DQ[2] provided by the second data register 291″_2 to the third data register 291″_3, the first multiplexer 292″_1 may output the first data DQ[1] provided by the first data register 291″_1 to the second data register 291″_2, and the 0-th multiplexer 292″_0 may output the 0-th data DQ[0] provided by the 0-th data register 291″_0 to the first data register 291″ 1.

For the eighteenth time t18 to the nineteenth time t19, the third data register 291″_3 may output the second data DQ[2] to the first_3 data pad dp1_3 through the data input/output buffer 295, the second multiplexer 292″_2 may output the first data DQ[1] provided by the second data register 291″_2 to the third data register 291″_3, and the first multiplexer 292″_1 may output the 0-th data DQ[0] provided by the first data register 291″_1 to the second data register 291″_2.

For the nineteenth time t19 to the twentieth time t20, the third data register 291″_3 may output the first data DQ[1] to the first_3 data pad dp1_3 through the data input/output buffer 295, and the second multiplexer 292″_2 may output the 0-th data DQ[0] provided by the second data register 291″_2 to the third data register 291″_3.

For the twentieth time t20 to the twenty-first time t21, the third data register 291″_3 may output the 0-th data DQ[0] to the first_3 data pad dp1_3 through the data input/output buffer 295.

For the eighteenth time t18 to the twenty-first time t21, the 0-th data register 291_0 may not perform an output operation to the first_0 data pad dp1_0. For the nineteenth time t19 to the twenty-first time t21, the first data register 291_1 may not perform an output operation to the first_1 data pad dp1_1. For the twentieth time t20 to the twenty-first time t21, the second data register 291_2 may not perform an output operation to the first_2 data pad dp1_2.

For the seventeenth time t17 to the twenty-first time t21, descriptions on the operations of the 0-th data register 291″_0, the first_1 data register 291″_1, the second data register 291″_2, the third data register 291″_3, the 0-th multiplexer 292″_0, the second multiplexer 292_1, and the second multiplexer 292″_2 may be respectively applied to the 4X-th first data registers 291″_0, . . . , 291″_4m-4, the (4X+1)-th first data registers 291″_1, . . . , 291″_4m-3, the (4X+2)-th first data registers 291″_2, . . . , 291″_4m-2, the (4X+3)-th first data registers 291″_3, . . . , 291″_4m-1, the 4X-th multiplexers 292″_0, . . . , 292″_4m-4, the (4X+1)-th multiplexers 292″_1, . . . , 292″_4m-3, and the (4X+2)-th multiplexers 292″_2, . . . , 292″_4m-2. The X may be an integer of equal to or greater than 0, and may be less than m.

Before the twenty-second time t22, the mode signal MODE_SEL on the second level MODE2 may be input to the multiplexers 292″_0, . . . , 292″_4m-2. The multiplexers 292″_0, . . . , 292″_4m-2 of the memory device 10″ may be operable in the second operation mode based on the mode signal MODE_SEL on the second level MODE2. In the second operation mode, the multiplexers 292″_0, . . . , 292″_4m-2 of the memory device 10″ may output the data with the second burst length that is less than the first burst length through the first data pads dp1_0 to dp1_4m-1.

For the twenty-second time t22, a read command is input, an after latency, the 0-th data DQ[0], the first data DQ[1], the second data DQ[2], and the third data DQ[3] may be output with the burst length of 8 on the first_0 data pad dp1_0, the first_1 data pad dp1_1, the first_2 data pad dp1_2, and the first_3 data pad dp1_3 for the twenty-third time t23 to the twenty-fourth time t24.

For the twenty-third time t23 to the twenty-fourth time t24, the 0-th data register 291″_0 may output the 0-th data DQ[0] to the first_0 data pad dp1_0 through the 0-th multiplexer 292″_0 and the data input/output buffer 295, the first_1 data register 291″_1 may output the first data DQ[1] to the first_1 data pad dp1_1 through the first multiplexer 292″_1 and the data input/output buffer 295, the second data register 291″_2 may output the second data DQ[2] to the first_2 data pad dp1_2 through the second multiplexer 292″_2 and the data input/output buffer 295, and the third data register 291″_3 may output the third data DQ[3] to the first_3 data pad dp1_3 through the data input/output buffer 295.

For the twenty-third time t23 to the twenty-fourth time t24, descriptions on the operations of the 0-th data register 291″_0, the first data register 291″_1, the second data register 291″_2, the third data register 291″_3, the 0-th multiplexer 292″_0, the second multiplexer 292_1, and the second multiplexer 292″_2 may be respectively applied to the 4X-th first data registers 291″_0, . . . , 291″_4m-4, the (4X+1)-th first data registers 291″_1, . . . , 291″_4m-3, the (4X+2)-th first data registers 291″_2, . . . , 291″_4m-2, the (4X+3)-th first data registers 291″_3, . . . , 291″_4m-1, the 4X-th multiplexers 292″_0, . . . , 292″_4m-4, the (4X+1)-th multiplexers 292″_1, . . . , 292″_4m-3, and the (4X+2)-th multiplexers 292″_2, . . . , 292″_4m-2. The X may be an integer of equal to or greater than 0, and may be less than m.

Referring to FIG. 17 and FIG. 18, a first minimum burst section tCCD_M1″ in the first operation mode MODE1 for the burst mode is four times a second minimum burst section tCCD_M2″ in the second operation mode MODE2 for the burst mode.

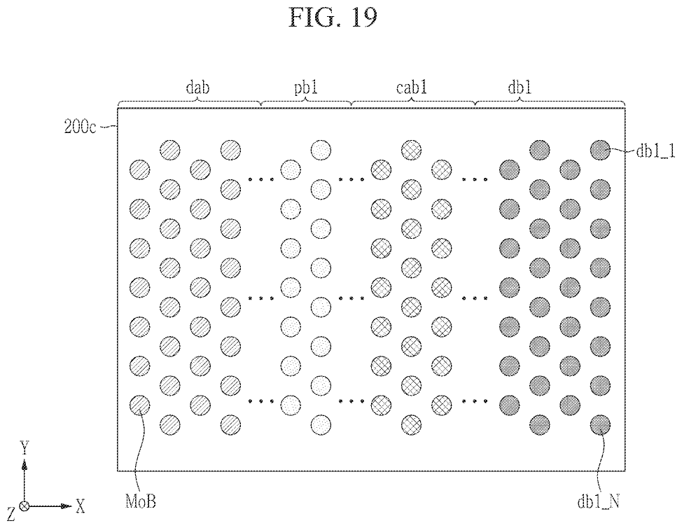

FIG. 19 shows another example of a memory system.

A base die 200c of FIG. 19 may be described in comparison to the base die 200 of FIG. 5, and their differences will be focused for ease of description. The configuration of the base die 200c that is not described will be replaced with the description on the corresponding configuration of the base die 200 of FIG. 5.

Referring to FIG. 19, the first direct access bumps dab of the base die 200c includes a mode bump MoB for receiving the mode signal MODE_SEL, and the operation mode on the burst mode of the memory device is controlled without intervention of the memory controller.

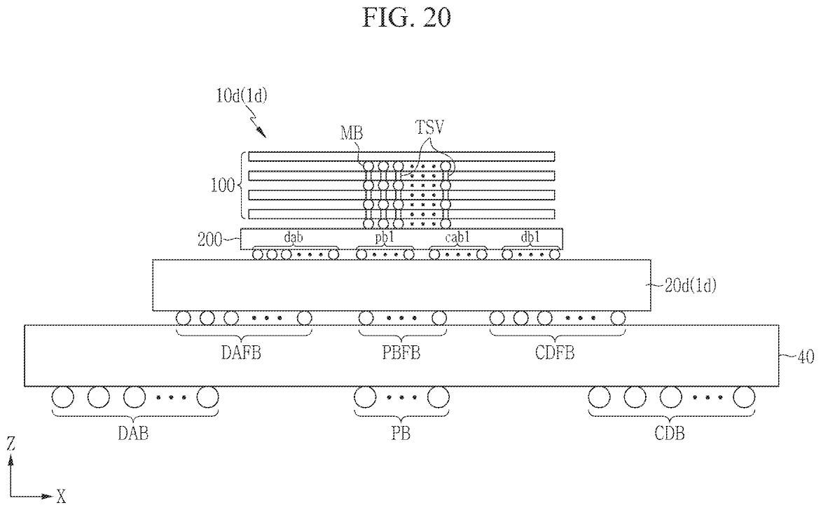

FIG. 20 shows another example of a memory system.

A memory system 1d of FIG. 20 may be described in comparison to the memory system 1 of FIG. 1 and FIG. 2, and their differences will be focused for ease of description. The configuration of the memory system 1d that is not described will be replaced with the description on the corresponding configuration of the memory system 1 of FIG. 1 and FIG. 2.

Referring to FIG. 20, the memory system 1d is manufactured with a 3D package. The memory device 10d of the memory system 1d may be disposed on the upper side of the memory controller 20d without disposing an additional interposer with respect to the third direction Z.

That is, the first direct access bumps dab, the first power bumps pb1, the first command and address bumps cab1, and the first data bumps db1 may be disposed on the upper side of the memory controller 20d.

The first direct access bumps dab and the second direct access bumps DAFB may be connected to each other in the memory controller 20d. The first power bumps pb1 and the third power bumps PBFB may be connected to each other in the memory controller 20d.

The memory controller 20d may receive control signals and data through the second control signal bumps CDFB, and may transmit channel commands, addresses, and channel data to the first command and address bumps cab1 and the first data bumps db1.

The memory system according to some implementations may universally exchange data with external devices through the mode signal without any change of the configuration in the viewpoint of the number of the data input/output bumps.

The memory system according to some implementations may adjust the number of the actually operated data input/output bumps from among the data input/output bumps to ease requisites of the size and the pitch of the configuration for the external device, and may reduce the cost for the process relating to the size and the pitch of the configuration for the external device.

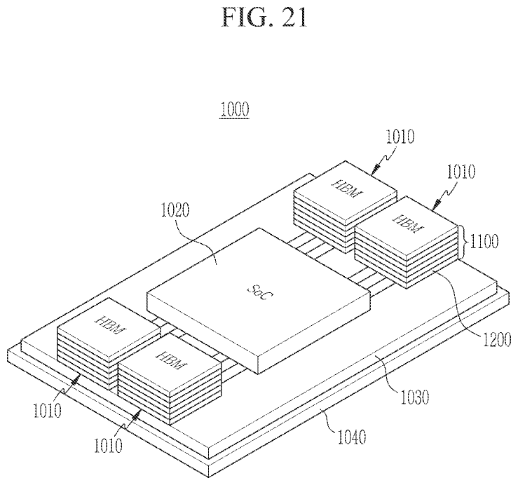

FIG. 21 shows a perspective view of a configuration of an example of a system device to which a memory system is applied.

Referring to FIG. 21, the system device 1000 is a semiconductor package, and may be a memory module including at least one memory device 1010 installed on the package substrate 1040 such as a printed circuit board and a system-on-chip (SOC) 1020.

An interposer 1030 may be selectively further provided on the package substrate 1040. The memory device 1010 may be formed in a chip-on-chip (CoC) type. The memory device 1010 may include a memory die 1100 including at least one core die stacked on the base die 1200. The memory die 1100 and the base die 1200 may be connected to each other by a through silicon via (TSV).

The base die 1200 may include an input/output gating circuit and a data input/output buffer for gating input/output data of the memory die 1100, and the base die 1200 may control the operation of the input/output gating circuit and the data input/output buffer according to the mode signal of the externally input to thus adjust the number of the data bumps for inputting/outputting data to/from the system-on-chip 1020. The input/output gating circuit and the data input/output buffer may perform the memory operation when the implementations described with reference to FIG. 1 to FIG. 20 are applied.

The memory device 1010 may, for example, be a high bandwidth memory (HBM) of equal to or greater than 500 GB/sec to 1 TB/sec.

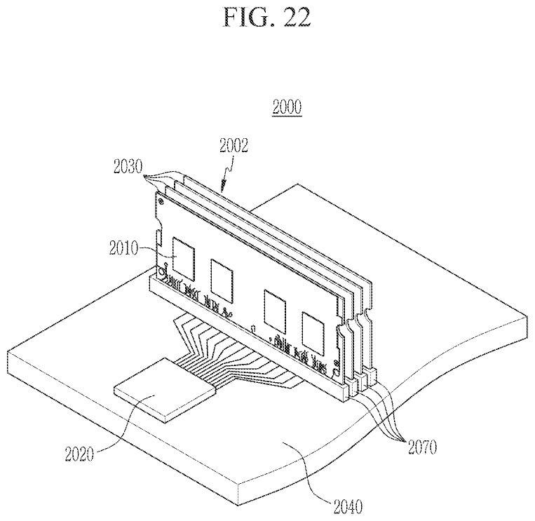

FIG. 22 shows a perspective view of another example of a system device to which a memory system is applied.

Referring to FIG. 22, the system device 2000 is a dual in-line memory module (DIMM) system in which semiconductor chips are installed on respective sides of the printed circuit board, and it may include a memory module 2002 including at least one PCB 2030 and a memory controller 2020. The memory controller 2020 may be mounted on the main board 2040, and the PCB 2030 may be electrically connected to the main board 2040 through connecting sockets.

The memory device 2010 may be formed in the chip-on-chip (CoC) type, and may be mounted on the respective sides of the PCB 2030. The memory controller 2020 and the memory device 2010 may be electrically connected to each other through the PCB 2030 and the bus in the main board 2040. According to some implementations, the memory device 2010 may have a stacking structure of the memory die and the base die.

The base die may include the input/output gating circuit and the data input/output buffer, and the base die may control the operations of the input/output gating circuit and the data input/output buffer according to the mode signal input to the outside, and may adjust the number of the data bumps for inputting/outputting data to/from the memory controller 2020. The input/output gating circuit and the data input/output buffer may perform the memory operation when the implementations described with reference to FIG. 1 to FIG. 20 are applied. The implementations described with reference to FIG. 1 to FIG. 20 are applied to perform the memory operation.

The memory device 2010 may, for example, be the high bandwidth memory (HBM) of equal to or greater than 500 GB/sec to 1 TB/sec.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While this disclosure has been described in connection with what is presently considered to be practical implementations, it is to be understood that the disclosure is not limited to the disclosed implementations and/or the examples, but, on the contrary, is intended to cover various modifications and equivalent arrangements included within the spirit and scope of the appended claims.

What is claimed is:

1. A memory device comprising:
a first core die and a second core die stacked in a first direction, the first core die including first memory cells and the second core die including second memory cells; and
a base die stacked in the first direction with the first and second core dies, the base die configured to output data of the first memory cells and the second memory cells provided by the first core die and the second core die through a through-via, the through-via passing through the first core die and the second core die in the first direction with different burst lengths based on a mode signal.

2. The memory device of claim 1, wherein
the base die is configured to output the data with a first burst length in a first operation mode and to output the data with a second burst length in a second operation mode based on the mode signal, and
a ratio of the first burst length and the second burst length is 1 to n, wherein n is an integer equal to or greater than 2.

3. The memory device of claim 1, wherein
a first data bump and a second data bump configured to output the data are disposed on one side of the base die,
the base die includes a first data register connected to the first data bump, a second data register connected to the second data bump, and a multiplexer disposed between the first data register and the second data register, and
the multiplexer is configured to provide first data, obtained from the first data register, to the first data bump in a first operation mode based on the mode signal.

4. The memory device of claim 3, wherein
the multiplexer is configured to provide the first data, obtained from the first data register, to the second data register in a second operation mode that is different from the first operation mode.

5. The memory device of claim 3, wherein
at a first time in a second operation mode that is different from the first operation mode, the second data register is configured to output second data to the second data bump, and the first data register is configured to not output data to the first data bump.

6. The memory device of claim 3, wherein
the base die includes a bump configured to receive the mode signal on the one side of the base die, and
the multiplexer is configured to receive the mode signal through the bump.

7. The memory device of claim 1, wherein
a first data bump, a second data bump, a third data bump, and a fourth data bump configured to output data are disposed on one side of the base die, and
the base die includes a first data register connected to the first data bump, a second data register connected to the second data bump, a third data register connected to the third data bump, a fourth data register connected to the fourth data bump, a first multiplexer disposed between the first data register and the second data register, a second multiplexer disposed between the second data register and the third data register, and a third multiplexer disposed between the third data register and the fourth data register.

8. A memory device comprising:
a first core die and a second core die stacked in a first direction, the first core die including first memory cells and the second core die including second memory cells; and
a base die stacked with the first and second core dies in the first direction, the base die configured to output data of the first memory cells and the second memory cells provided by the first core die and the second core die through a through-via, the through-via passing through the first core die and the second core die in the first direction, the base die including a first data bump and a second data bump connected to an external pad on one side and configured to output the data, a first data register connected to the first data bump, a second data register connected to the second data bump, and a multiplexer disposed between the first data register and the second data register.

9. The memory device of claim 8, wherein
the base die is configured to output the data with different burst lengths based on an external mode signal.

10. The memory device of claim 9, wherein
one side of the base die includes a bump configured to receive the mode signal, and
the multiplexer is configured to receive the mode signal through the bump.

11. The memory device of claim 9, wherein
the base die is configured to output the data with a first burst length in a first operation mode and to output the data with a second burst length in a second operation mode based on the mode signal, and
a ratio of the first burst length and the second burst length is 1 to n, wherein n is an integer equal to or greater than 2.

12. The memory device of claim 11, wherein
the multiplexer is configured to provide first data, obtained from the first data register, to the second data register in the second operation mode.

13. The memory device of claim 11, wherein
the second data bump is configured to output second data to the external pad, and the first data bump is configured to not output data to the external pad at a first time in the second operation mode.

14. The memory device of claim 8, wherein
the base die includes data bumps including the first data bump and the second data bump,
the data bumps are combined with external pads including the external pad and are configured to output the data of the first second memory cells and the second memory cells, and
the number of the external pads is less than the number of the data bumps.

15. The memory device of claim 14, wherein
a ratio of the number of the external pads and the number of the data bumps is 1 to n, wherein n is an integer equal to or greater than 2.

16. A memory system comprising:
a memory device including a first core die, a second core die, and a base die stacked in a first direction, the first core die including first memory cells, the second core die including second memory cells, the base die configured to output data of the first memory cells and the second memory cells provided by the first core die and the second core die through a through-via, and the through-via passing through the first core die and the second core die in the first direction to first data bumps; and
a memory controller configured to exchange the data with the memory device through second data bumps, wherein the number of the second data bumps is less than the number of the first data bumps.

17. The memory system of claim 16, wherein
the base die is configured to output the data with different burst length based on a mode signal provided by the memory controller.

18. The memory system of claim 17, wherein
the base die is configured to output the data with a first burst length in a first operation mode and to output the data with a second burst length in a second operation mode based on the mode signal, and
a ratio of the first burst length and the second burst length is 1 to n, wherein n is an integer equal to or greater than 2.

19. The memory system of claim 16, wherein
the base die includes a first data register and a second data register, each connected to one data bump of the first data bumps, and a multiplexer disposed between the first data register and the second data register.

20. The memory system of claim 16, wherein
a ratio of the number of the second data bumps and the number of the first data bumps is 1 to n, wherein n is an integer equal to or greater than 2.
